(19) United States
(12) Patent Application Publication
(10) Pub. No.: US 2012/0276715 A1
(43) Pub. Date: Nov. 1, 2012

(54) METHOD FOR MANUFACTURING COMBINED SUBSTRATE HAVING SILICON CARBIDE SUBSTRATE

(75) Inventors: Tsutomu Hori, Itami-shi (JP); Shin Harada, Osaka-shi (JP); Makoto Sasaki, Itami-shi (JP); Hiroki Inoue, Itami-shi (JP); Kyoko Okita, Itami-shi (JP); Yasuo Namikawa, Osaka-shi (JP); Satomi Itoh, Osaka-shi (JP)

(73) Assignee: SUMITOMO ELECTRIC INDUSTRIES LTD., OSAKA-SHI OSAKA (JP)

(21) Appl. No.: 13/395,795

(22) PCT Filed: Jun. 17, 2011
(86) PCT No.: PCT/JP2011/063953

§ 371 Date: Mar. 13, 2012

(30) Foreign Application Priority Data
Oct. 18, 2010 (JP) 2010-233721

(51) Int. Cl. H01L 21/762

(52) U.S. Cl. 438/455; 257/E21.567

(57) ABSTRACT

A connected substrate having a supporting portion and first and second silicon carbide substrates is prepared. The first silicon carbide substrate has a first backside surface connected to the supporting portion, a first front-side surface, and a first side surface connecting the first backside surface and the first front-side surface to each other. The second silicon carbide substrate has a second backside surface connected to the supporting portion, a second front-side surface, and a second side surface connecting the second backside surface and the second front-side surface to each other and forming a gap between the first side surface and the second side surface. A filling portion for filling the gap is formed. Then, the first and second front-side surfaces are polished. Then, the filling portion is removed. Then, a closing portion for closing the gap is formed.

### TECHNICAL FIELD

The present invention relates to a method for manufacturing a combined substrate, in particular, a method for manufacturing a combined substrate having a plurality of silicon carbide substrates.

### BACKGROUND ART

In recent years, compound semiconductors have been adopted as semiconductor substrates for use in manufacturing semiconductor devices. For example, silicon carbide has a band gap larger than that of silicon, which has been used more commonly. Hence, a semiconductor device employing a silicon carbide substrate advantageously has a large breakdown voltage, low on-resistance, and properties less likely to decrease in a high temperature environment.

In order to efficiently manufacture such semiconductor devices, the substrates need to be large in size to some extent. According to U.S. Pat. No. 7,314,520 (Patent Literature 1), a silicon carbide substrate of 76 mm (3 inches) or greater can be manufactured.

### CITATION LIST

### Patent Literature

PTL 1: U.S. Pat. No. 7,314,520

### SUMMARY OF INVENTION

### Technical Problem

Industrially, the size of a silicon carbide substrate is still limited to approximately 100 mm (4 inches). Accordingly, semiconductor devices cannot be efficiently manufactured using large substrates, disadvantageously. This disadvantage becomes particularly serious in the case of using a property of a plane other than the (0001) plane in silicon carbide of hexagonal system. Hereinafter, this will be described.

A silicon carbide substrate small in defect is usually manufactured by slicing a silicon carbide ingot obtained by growth in the (0001) plane, which is less likely to cause stacking fault. Hence, a silicon carbide substrate having a plane orientation other than the (0001) plane is obtained by slicing the ingot not in parallel with its grown surface. This makes it difficult to sufficiently secure the size of the substrate, or many portions in the ingot cannot be used effectively. For this reason, it is particularly difficult to efficiently manufacture a semiconductor device that employs a plane other than the (0001) plane of silicon carbide.

Instead of increasing the size of such a silicon carbide substrate, it is considered to use a combined substrate having a plurality of silicon carbide substrates and a supporting portion connected to each of the plurality of silicon carbide substrates. Even if the supporting portion has a high crystal defect density, problems are unlikely to take place. Hence, a large supporting portion can be prepared relatively readily. The size of the combined substrate can be increased by increasing the number of silicon carbide substrates disposed on the supporting portion, as required.

Although each of the silicon carbide substrates and the supporting portion are connected to each other in the combined substrate, adjacent silicon carbide substrates may not be connected to each other or may not be sufficiently connected to each other. Accordingly, a gap may be formed between the adjacent silicon carbide substrates. If the combined substrate having such a gap is used to manufacture a semiconductor device, foreign matters are likely to remain in this gap in the manufacturing process. In particular, a polishing agent for CMP (Chemical Mechanical Polishing) is likely to remain therein. The foreign matters can be a factor that causes process variation in the process of manufacturing a semiconductor device using the combined substrate.

The present invention has been made in view of the foregoing problem, and has its object to provide a method for manufacturing a combined substrate, so as to restrain process variation resulting from a gap between silicon carbide substrates in a process of manufacturing a semiconductor device using the combined substrate having the silicon carbide substrates.

### Solution to Problem

A method for manufacturing a combined substrate in the present invention includes the following steps.

A connected substrate is prepared which has a supporting portion and first and second silicon carbide substrates. The first silicon carbide substrate has a first backside surface connected to the supporting portion, a first front-side surface opposite to the first backside surface, and a first side surface connecting the first backside surface and the first front-side surface to each other. The second silicon carbide substrate has a second backside surface connected to the supporting portion, a second front-side surface opposite to the second backside surface, and a second side surface connecting the second backside surface and the second front-side surface to each other and forming a gap between the first side surface and the second side surface. A filling portion for filling the gap is formed. Then, the first and second front-side surfaces are polished. Then, the filling portion is removed. Then, a closing portion for closing the gap is formed.

According to this manufacturing method, the gap between the first and second silicon carbide substrates is closed by the closing portion. Accordingly, foreign matters are prevented from being accumulated in the gap in the process of manufacturing a semiconductor device using the combined substrate.

Further, when the first and second front-side surfaces are polished, the gap between the first and second silicon carbide substrates is filled with the filling portion. Accordingly, foreign matters such as a polishing agent can be prevented from remaining in the gap after the polishing.

Further, at the time of the formation of the closing portion, the filling portion has been already removed. Accordingly, in the step of forming the closing portion or a subsequent step, an adverse effect otherwise caused by the existence of the filling portion over the step can be prevented.

Preferably, the step of forming the closing portion is performed by epitaxially growing the closing portion on the first and second silicon carbide substrates. In this way, the crystal structure of the closing portion can be optimized to be suitable for the semiconductor device.

Preferably, the step of removing the filling portion is performed by means of a dry process. In this way, as compared with a case where the step of removing the filling portion is performed by means of a wet process, foreign matters can be prevented from remaining in the gap from which the filling portion has been removed.

Preferably, the step of forming the filling portion is performed using at least one of a metal, a resin, and silicon. Accordingly, the step of removing the filling portion can be performed readily.

Preferably, the step of removing the filling portion and the step of forming the closing portion are performed in a continuous manner in a chamber (90). Accordingly, the first and second silicon carbide substrates can be prevented from being contaminated between the steps.

### Advantageous Effects of Invention

As apparent from the description above, according to the present invention, process variation resulting from a gap between silicon carbide substrates can be restrained in a process of manufacturing a semiconductor device using a combined substrate having silicon carbide substrates.

### BRIEF DESCRIPTION OF DRAWINGS

FIG. 1 is a plan view schematically showing a configuration of a combined substrate in a first embodiment of the present invention.

FIG. 2 is a schematic cross sectional view taken along a line II-II in FIG. 1.

FIG. 3 is a partial enlarged view of FIG. 2.

FIG. 4 is a flowchart schematically showing a method for manufacturing the combined substrate in the first embodiment of the present invention.

FIG. 5 is a plan view schematically showing a first step of a method for manufacturing the combined substrate in the first embodiment of the present invention.

FIG. 6 is a schematic cross sectional view taken along a line VI-VI in FIG. 1.

FIG. 7 is a partial cross sectional view schematically showing a second step of the method for manufacturing the combined substrate in the first embodiment of the present invention.

FIG. 8 is a cross sectional view schematically showing a third step of the method for manufacturing the combined substrate in the first embodiment of the present invention.

FIG. 9 is a cross sectional view schematically showing a fourth step of the method for manufacturing the combined substrate in the first embodiment of the present invention.

FIG. 10 is a cross sectional view schematically showing a fifth step of the method for manufacturing the combined substrate in the first embodiment of the present invention.

FIG. 11 is a cross sectional view schematically showing a sixth step of the method for manufacturing the combined substrate in the first embodiment of the present invention.

FIG. 12 is a cross sectional view schematically showing a seventh step of the method for manufacturing the combined substrate in the first embodiment of the present invention.

FIG. 13 is a cross sectional view schematically showing an eighth step of the method for manufacturing the combined substrate in the first embodiment of the present invention.

FIG. 14 is a cross sectional view schematically showing a configuration of a combined substrate in a second embodiment of the present invention.

FIG. 15 is a partial cross sectional view schematically showing a configuration of a semiconductor device in a third embodiment of the present invention.

FIG. 16 is a schematic flowchart showing a method for manufacturing the semiconductor device in the third embodiment of the present invention.

FIG. 17 is a partial cross sectional view schematically showing a first step of the method for manufacturing the semiconductor device in the third embodiment of the present invention.

FIG. 18 is a partial cross sectional view schematically showing a second step of the method for manufacturing the semiconductor device in the third embodiment of the present invention.

FIG. 19 is a partial cross sectional view schematically showing a third step of the method for manufacturing the semiconductor device in the third embodiment of the present invention.

FIG. 20 is a partial cross sectional view schematically showing a fourth step of the method for manufacturing the semiconductor device in the third embodiment of the present invention.

FIG. 21 is a partial cross sectional view schematically showing a fifth step of the method for manufacturing the semiconductor device in the third embodiment of the present invention.

### DESCRIPTION OF EMBODIMENTS

The following describes embodiments of the present invention with reference to figures.

### First Embodiment

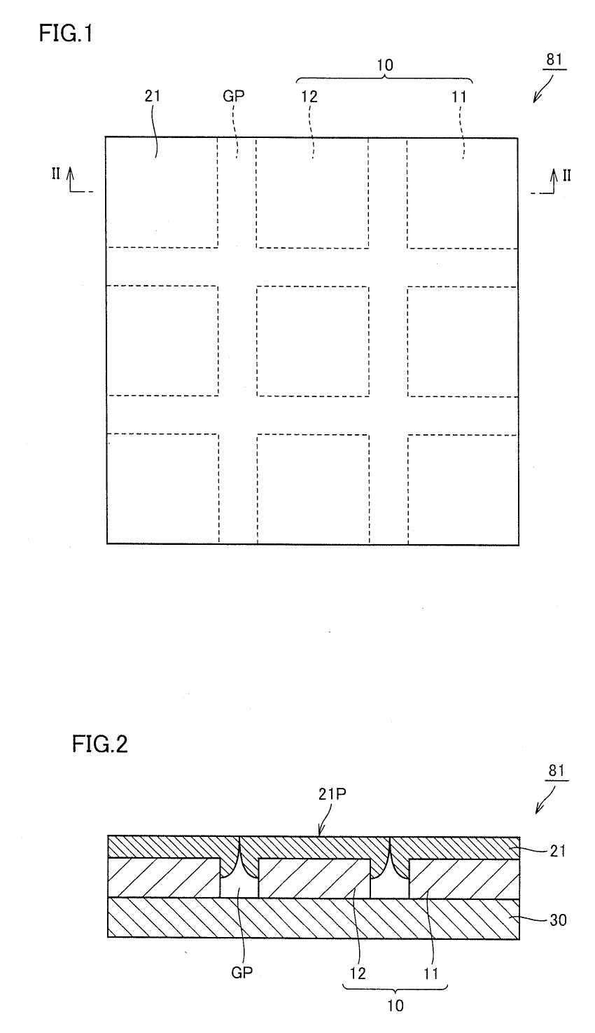

As shown in FIG. 1 to FIG. 3, a combined substrate 81 of the present embodiment has a supporting portion 30, a silicon carbide substrate group 10, and a closing portion 21. Silicon carbide substrate group 10 includes silicon carbide substrates 11 and 12 (first and second silicon carbide substrates). For ease of description, only silicon carbide substrates 11 and 12 of silicon carbide substrate group 10 may be explained.

Each one in silicon carbide substrate group 10 has a front-side surface and a backside surface opposite to each other, and has a side surface connecting the front-side surface and the backside surface to each other. For example, silicon carbide substrate 11 has a backside surface B1 (first backside surface) connected to supporting portion 30, a front-side surface T1 (first front-side surface) opposite to backside surface B1, and a side surface S1 (first side surface) connecting backside surface B1 and front-side surface T1 to each other. Silicon carbide substrate 12 has a backside surface B2 (second backside surface) connected to supporting portion 30, a front-side surface T2 (second front-side surface) opposite to backside surface B2, and a side surface S2 (second side surface) connecting backside surface B2 and front-side surface T2 to each other.

The backside surface of each one in silicon carbide substrate group 10 is connected to supporting portion 30, thereby fixing the silicon carbide substrates of silicon carbide substrate group 10 to one another. The front-side surfaces of the silicon carbide substrates of silicon carbide substrate group 10 (front-side surfaces T1 and T2, and the like) are disposed to be flush with one another. Combined substrate 81 has a surface larger than that of each one in silicon carbide substrate group 10. Hence, in the case of using combined substrate 81, semiconductor devices can be manufactured more efficiently than in the case of using each one in silicon carbide substrate group 10 solely. Further, in the present embodiment, each one in silicon carbide substrate group 10 is a single-crystal substrate. This makes it possible to efficiently manufacture semiconductor devices each having single-crystal silicon carbide. However, depending on the purpose of use of the combined substrate, each one in silicon carbide substrate group 10 may not be a single-crystal substrate.

Further, a gap GP is formed between the side surfaces of adjacent silicon carbide substrates of silicon carbide substrate group 10. For example, gap GP is formed between side surface S1 of silicon carbide substrate 11 and side surface S2 of silicon carbide substrate 12. Preferably, gap GP includes a portion having a width LG of 100 μm or smaller. More preferably, gap GP has a width having an average of 100 μm or smaller. Further preferably, the entire gap GP has a width of 100 μM or smaller.

Closing portion 21 is provided on silicon carbide substrates 11 and 12. Specifically, as shown in FIG. 3, closing portion 21 is provided on front-side surface T1, front-side surface T2, an end portion of side surface S1 at the front-side surface T1 side, and an end portion of side surface S2 at the front-side surface T2 side. Further, closing portion 21 closes gap GP. Specifically, closing portion 21 provides a remaining space between supporting portion 30 and closing portion 21 and isolates this space from external space. Preferably, closing portion 21 is made of silicon carbide. Further, closing portion 21 preferably has at least portions epitaxially grown on silicon carbide substrates 11 and 12. Further, closing portion 21 preferably has a portion extending upwardly from each of front-side surfaces T1 and T2 and having a thickness LB equal to or greater than 1/100 of the minimum value of width LG of gap GP. More preferably, thickness LB is equal to or greater than 1/100 of the average value of width LG. Further preferably, thickness LB is equal to or greater than 1/100 of the maximum value of width LG.

Supporting portion 30 is preferably made of silicon carbide. More preferably, supporting portion 30 has a micro pipe density higher than that of each one of silicon carbide substrate group 10. Further, preferably, supporting portion 30 has portions located on the backside surfaces of those of silicon carbide substrate group 10 and epitaxially grown onto these backside surfaces. More preferably, supporting portion 30 is entirely epitaxially grown onto silicon carbide substrate group 10.

Each one of silicon carbide substrate group 10 and supporting portion 30 have the following exemplary dimensions. That is, each one in silicon carbide substrate group 10 has a planar shape of square of 20×20 mm and has a thickness of 400 μM. Supporting portion 30 has a thickness of 400 μm.

The following describes a method for manufacturing combined substrate 81.

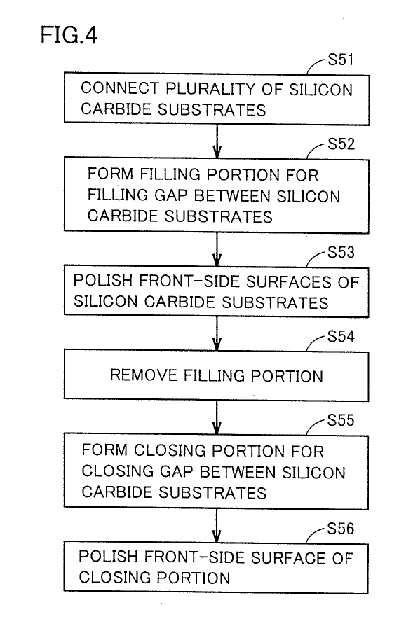

As shown in FIG. 4, a step (step S51) is first performed to connect silicon carbide substrate group 10. Details thereof will be described below.

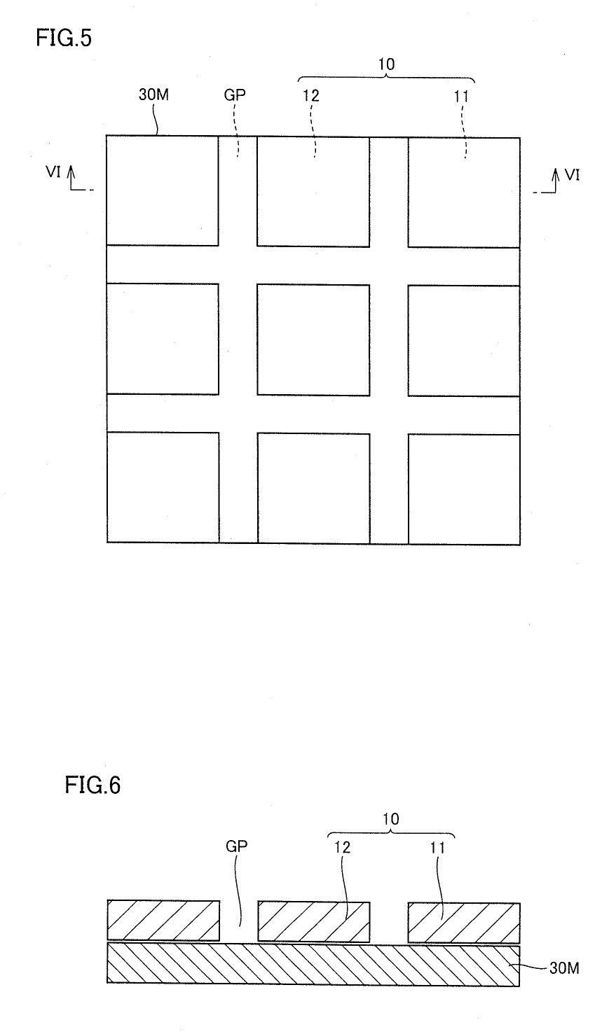

As shown in FIG. 5 and FIG. 6, a supporting portion 30M made of silicon carbide and silicon carbide substrate group 10 are prepared. Supporting portion 30M may have any crystal structure. Preferably, the backside surface of each one in silicon carbide substrate group 10 may be a surface formed as a result of slicing, specifically, a surface (as-sliced surface) formed as a result of slicing and not polished after the slicing. In this case, the backside surface can be provided with moderate undulations.

Next, silicon carbide substrate group 10 and supporting portion 30M are disposed face to face with each other such that the backside surface of each one in silicon carbide substrate group 10 faces the front-side surface of supporting portion 30M. Specifically, silicon carbide substrate group 10 may be placed on supporting portion 30M, or supporting portion 30M may be placed on silicon carbide substrate group 10.

Next, the atmosphere is adapted by reducing pressure of the atmospheric air. The pressure of the atmosphere is preferably higher than 10⁻¹ Pa and is lower than 10⁴ Pa.

The atmosphere described above may be an inert gas atmosphere. An exemplary inert gas usable is a noble gas such as He or Ar; a nitrogen gas; or a mixed gas of the noble gas and nitrogen gas. Further, the pressure in the atmosphere is preferably 50 kPa or smaller, and is more preferably 10 kPa or smaller.

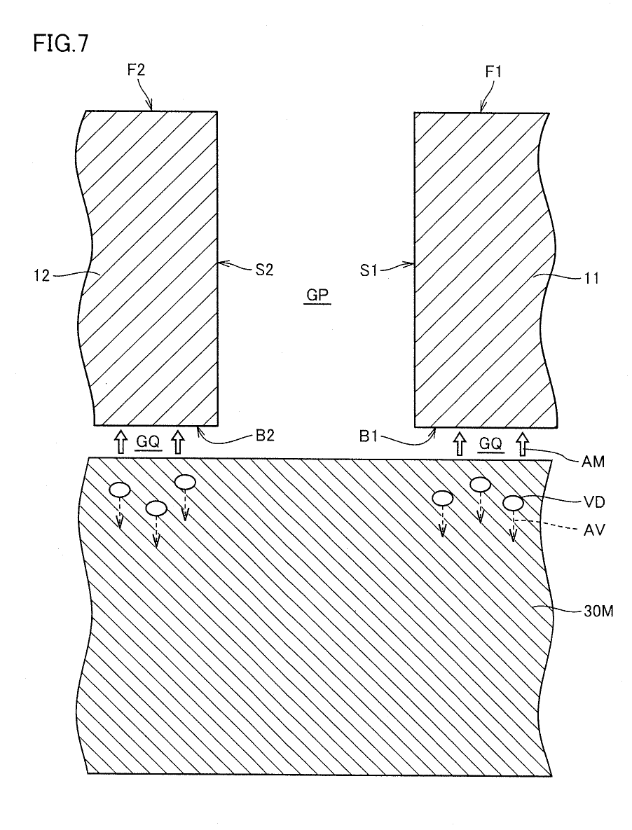

As shown in FIG. 7, at this point of time, each of silicon carbide substrates 11 and 12 and supporting portion 30M are just placed and stacked on one another and have not been connected to one another yet. Between each of backside surfaces B1 and B2 and supporting portion 30M, slight undulations in backside surfaces B1 and B2, or slight undulations in the front-side surface of supporting portion 30M provide clearances GQ, microscopically.

Next, silicon carbide substrate group 10 including silicon carbide substrates 11 and 12 and supporting portion 30M are heated. This heating is performed to cause the temperature of supporting portion 30M to reach a temperature at which silicon carbide can sublime, for example, a temperature of not less than 1800° C. and not more than 2500° C., more preferably, not less than 2000° C. and not more than 2300° C. The heating time is set at, for example, 1 to 24 hours. Further, the heating is performed to cause each one in silicon carbide substrate group 10 to have a temperature smaller than that of supporting portion 30M. Namely, a temperature gradient is formed such that temperature is decreased from below to above in FIG. 7. The temperature gradient is, preferably, not less than 1° C./cm and not more than 200° C./cm, more preferably, not less than 10° C./cm and not more than 50° C./cm between supporting portion 30M and each of silicon carbide substrates 11 and 12. When the temperature gradient is thus provided in the thickness direction (longitudinal direction in FIG. 7), a boundary at the supporting portion 30M side (lower side in FIG. 7) among the boundaries defining clearances GQ has a temperature higher than that of each of the boundaries at the silicon carbide substrate 11 side and the silicon carbide substrate 12 side (upper side in FIG. 7). As a result, sublimation of silicon carbide into clearances GQ is more likely to take place from supporting portion 30M as compared with sublimation from silicon carbide substrates 11 and 12. Conversely, recrystallization reaction of the sublimation gas in clearances GQ is more likely to take place on silicon carbide substrates 11 and 12, i.e., on backside surfaces B1 and B2 as compared with recrystallization reaction on supporting portion 30M. As a result, in clearances GQ, as indicated by arrows AM in the figure, mass transfer of silicon carbide takes place due to the sublimation and the recrystallization.

As a result of the mass transfer indicated by arrows AM, each of clearances GQ is divided into a multiplicity of voids VD. Voids VD are then transferred as indicated by arrows AV indicating a direction opposite to the direction of arrows AM. Further, as a result of this mass transfer, supporting portion 30M regrows on silicon carbide substrates 11 and 12. Namely, supporting portion 30M is reformed due to the sublimation and the recrystallization. This reformation gradually proceeds from a region close to backside surfaces B1 and B2. Namely, the portion of supporting portion 30 on the backside surface of silicon carbide substrate group 10 is gradually epitaxially grown onto this backside surface. Preferably, supporting portion 30M is entirely reformed.

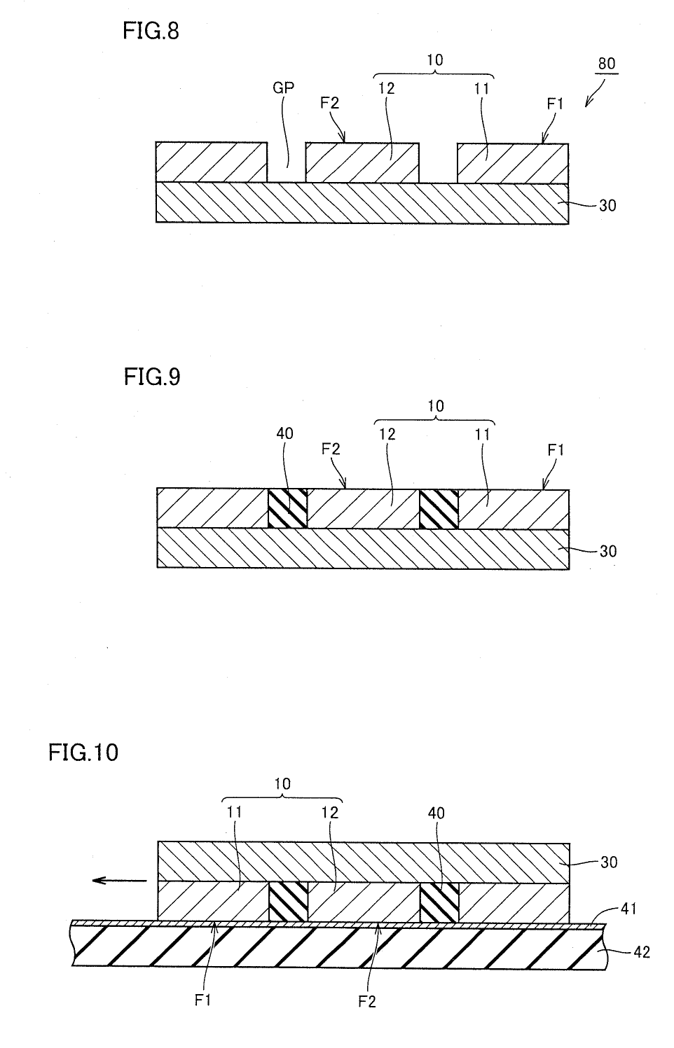

Referring to FIG. 8, as a result of the reformation, supporting portion 30M is changed into supporting portion 30 having a portion with a crystal structure corresponding to those of silicon carbide substrates 11 and 12. Further, the space corresponding to clearance GQ is changed into voids VD in supporting portion 30, and many of them are moved to get out of supporting portion 30 (toward the lower side in FIG. 7). As a result, there is provided a connected substrate 80 having silicon carbide substrate group 10 including the silicon carbide substrates having their backside surfaces connected to supporting portion 30. Supporting portion 30 and silicon carbide substrate group 10 are arranged in connected substrate 80 in the same manner as in combined substrate 81 (FIG. 1 to FIG. 3).

As shown in FIG. 9, a filling portion 40 is formed to fill gap GP.

Filling portion 40 may be made of a material such as silicon (Si). In this case, filling portion 40 can be formed by means of, for example, a sputtering method, a deposition method, a CVD method, or pouring of a solution.

Alternatively, the filling portion may be made of a metal. For example, there can be used a metal including at lease one of aluminum (Al), titanium (Ti), vanadium (V), chromium (Cr), manganese (Mn), iron (Fe), cobalt (Co), nickel (Ni), copper (Cu), zinc (Zn), yttrium (Y), zirconium (Zr), niobium (Nb), molybdenum (Mo), ruthenium (Ru), rhodium (Rh), palladium (Pd), tin (Sn), tungsten (W), rhenium (Re), platinum (Pt), and gold (Au). It should be noted that it is preferable not to use aluminum, titanium, and vanadium of the metals listed above, in view of reliability of the semiconductor device to be manufactured using combined substrate 81. In this case, filling portion 40 can be formed by, for example, the sputtering method, the deposition method, or the pouring of a solution.

Alternatively, filling portion 40 may be made of a resin. Examples of the resin usable include at least one of acrylic resin, urethane resin, polypropylene, polystyrene, and polyvinyl chloride. In this case, filling portion 40 can be formed by means of, for example, pouring.

As shown in FIG. 10, front-side surfaces F1 and F2 are polished by means of CMP. Specifically, front-side surfaces F1 and F2 are rubbed by a polishing cloth 42 supplied with a polishing agent 41 for CMP.

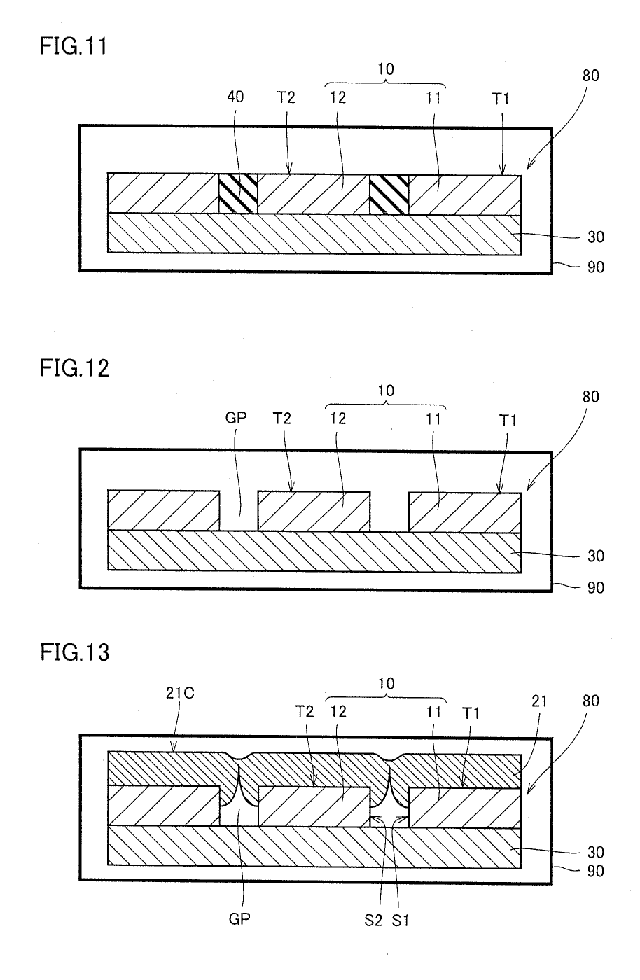

Further, referring to FIG. 11, as a result of the polishing, front-side surfaces F1 and F2 are changed into more planarized front-side surfaces T1 and T2. Next, connected substrate 80 is transported into a chamber 90.

Referring to FIG. 12, in chamber 90, a dry process is performed to remove filling portion 40. This dry process is a process other than a wet process, specifically, is dry etching. It should be noted that this dry process may also serve to clean front-side surfaces T1 and T2.

As shown in FIG. 13, closing portion 21 is formed to close gap GP. Preferably, closing portion 21 is formed by epitaxially growing closing portion 21 on the front-side surfaces of silicon carbide substrate group 10. In addition to growth perpendicular to front-side surfaces T1 and T2, i.e., growth in the longitudinal direction in FIG. 13, this epitaxial growth includes growth in the lateral direction. As a result of the growth in the lateral direction, closing portion 21 closes the gap. In order to attain the closure more securely, it is preferable that points from which the epitaxial growth is started include front-side surfaces T1 and T2, the end portion of side surface S1 at the front-side surface T1 side, and the end portion of side surface S2 at the front-side surface T2 side. A heating temperature required for the epitaxial growth is, for example, not less than 1550° C. and not more than 1600° C. More preferably, this formation is performed in chamber 90 in a manner continuous to the above-described step of removing filling portion 40. Here, the term “continuous” is intended to indicate that connected substrate 80 is never taken out of chamber 90 between the steps while there may be or may not be a time interval between the steps.

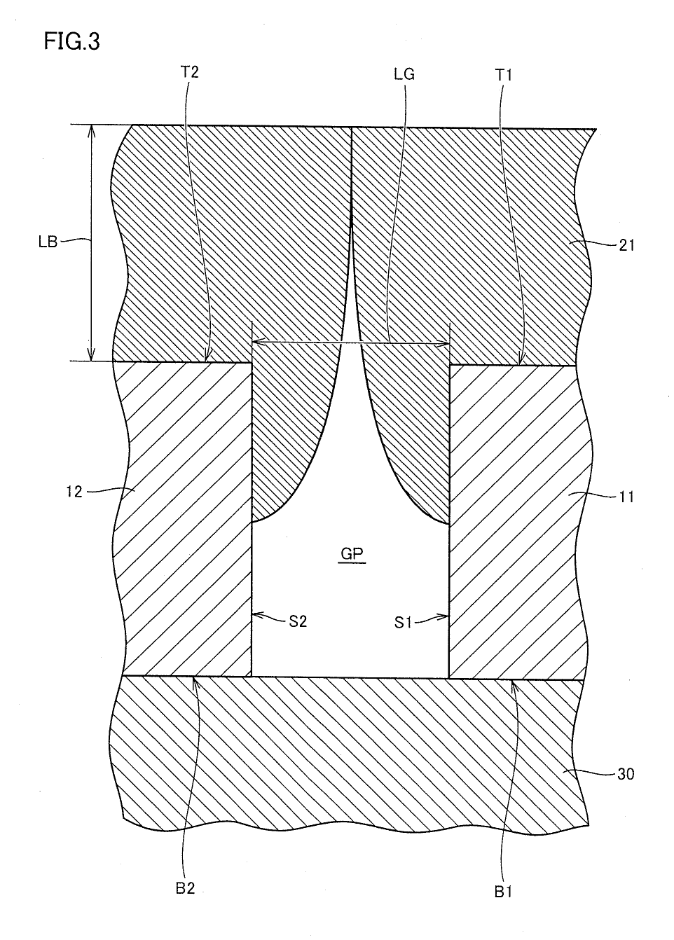

In this way, combined substrate 81 (FIG. 2) is obtained. It should be noted that when the surface of closing portion 21 needs to have smoothness, there may be provided an additional step of polishing the surface of closing portion 21. In this way, closing portion 21 is provided with a smooth surface 21P (FIG. 2).

It should be noted that in the above-described manufacturing method, the dry process in chamber 90 is employed as the method of removing filling portion 40 (FIG. 10), but a wet process in an etching bath may be used instead. An etchant for the wet process is desirably likely to melt filling portion 40 and unlikely to melt silicon carbide. In the case where filling portion 40 is made of silicon, hydrofluoric-nitric acid can be used as the etchant. In the case where filling portion 40 is made of a metal, one of hydrochloric acid, sulfuric acid, and aqua regia can be used as the etchant, depending on a type of the metal. In the case where filling portion 40 is made of a resin, a solvent, in particular, an organic solvent can be used.

According to the method for manufacturing combined substrate 81 in the present embodiment, gap GP between silicon carbide substrates 11 and 12 is closed by closing portion 21 (FIG. 13). In this way, in the process of manufacturing a semiconductor device using combined substrate 81, foreign matters can be prevented from being accumulated in this gap GP. Further, an adverse effect otherwise caused by the existence of gap GP over uniformity in applying an resist in a photolithography method can be prevented, which leads to improved precision in photolithography.

Further, during the polishing of front-side surfaces F1 and F2 (FIG. 10), gap GP between silicon carbide substrates 11 and 12 is filled with filling portion 40. Accordingly, foreign matters such as a polishing agent can be prevented from remaining in this gap GP after the polishing. Further, during the polishing, edges of silicon carbide substrates 11 and 12 can be prevented from being chipped.

Further, at the time of the formation of closing portion 21 (FIG. 13), filling portion 40 has been already removed. Accordingly, in the step of forming closing portion 21 or a subsequent step, an adverse effect otherwise caused by the existence of filling portion 40 over the step can be prevented. Specifically, in the case where silicon carbide is epitaxially grown when manufacturing a semiconductor device using combined substrate 81, a high temperature of approximately 1550° C. to approximately 1600° C. is generally employed. Hence, the existence of filling portion 40, which has a low heat resistance, is likely to be a factor of process variation. For example, in the case where filling portion 40 is made of silicon, the high temperature results in generation of a solution of silicon, which may affect composition of portions adjacent thereto.

Preferably, the step (FIG. 13) of forming closing portion 21 is performed by epitaxially growing closing portion 21 on silicon carbide substrates 11 and 12. In this way, the crystal structure of closing portion 21 can be optimized to be suitable for the semiconductor device.

Preferably, the step of removing filling portion 40 (FIG. 12) is performed by means of the dry process. In this way, as compared with a case where the step of removing filling portion 40 is performed by means of a wet process, foreign matters can be prevented from remaining in gap GP from which filling portion 40 has been removed. Specifically, no etchant in the wet process remains therein.

Preferably, the step of forming filling portion 40 is performed using at least one of a metal, a resin, and silicon. In this way, the step of removing filling portion 40 can be performed readily.

Preferably, the step of removing filling portion 40 and the step of forming closing portion 21 are performed in a continuous manner in chamber 90. Accordingly, silicon carbide substrates 11 and 12 can be prevented from being contaminated between the steps.

According to combined substrate 81 (FIG. 1 to FIG. 3) of the present embodiment, there can be obtained combined substrate 81 having an area corresponding to the total of areas of silicon carbide substrates 11 and 12. In this way, a semiconductor device can be manufactured more efficiently as compared with a case where each of silicon carbide substrates 11 and 12 is used solely to manufacture a semiconductor device.

Further, according to combined substrate 81, gap GP between silicon carbide substrates 11 and 12 is closed by closing portion 21. Accordingly, foreign matters are not accumulated in gap GP in the process of manufacturing semiconductor devices using combined substrate 81.

Preferably, each of silicon carbide substrates 11 and 12 has a single-crystal structure. By combining silicon carbide substrates 11 and 12, the area provided by the silicon carbide substrates, each of which has a difficulty in having a large area, can be substantially larger. In this way, a semiconductor device having single-crystal silicon carbide can be manufactured efficiently.

Preferably, closing portion 21 is made of silicon carbide. Accordingly, closing portion 21 can be used as a portion made of silicon carbide in the semiconductor device.

Preferably, closing portion 21 has at least a portion epitaxially grown on silicon carbide substrates 11 and 12. In this way, the crystal structure of closing portion 21 can be optimized to be suitable for the semiconductor device.

Preferably, supporting portion 30 is made of silicon carbide. Accordingly, various physical properties of each of silicon carbide substrates 11 and 12 and supporting portion 30 can be close to each other. Further, supporting portion 30 can be used as a portion made of silicon carbide in the semiconductor device.

Preferably, supporting portion 30 has a micro pipe density higher than that of each of silicon carbide substrates 11 and 12. Accordingly, supporting portion 30 having more micropipe defects can be used, thereby further facilitating the manufacturing of combined substrate 81.

Preferably, gap GP has width LG (FIG. 3) of 100 μm or smaller. In this way, gap GP can be closed more securely by closing portion 21.

Preferably, closing portion 21 has thickness LB (FIG. 3) of not less than 1/100 of the width of gap GP. Accordingly, gap GP can be closed by closing portion 21 more securely.

Preferably, supporting portion 30 has an impurity concentration higher than that of each one in silicon carbide substrate group 10. In other words, the impurity concentration of supporting portion 30 is relatively high and the impurity concentration of silicon carbide substrate group 10 is relatively low. Since the impurity concentration of supporting portion 30 is thus high, the resistivity of supporting portion 30 can be small, whereby supporting portion 30 can be used as a portion having a low resistivity in the semiconductor device. Meanwhile, since the impurity concentration of silicon carbide substrate group 10 is thus low, the crystal defects thereof can be reduced more readily. As the impurity, for example, nitrogen, phosphorus, boron, or aluminum can be used.

The following describes a particularly preferable embodiment of silicon carbide substrate group 10 including silicon carbide substrates 11 and 12.

The crystal structure of silicon carbide of each silicon carbide substrate of silicon carbide substrate group 10 is preferably of hexagonal system, and is more preferably of 4H type or 6H type. More preferably, the front-side surface (such as front-side surface F1) of the silicon carbide substrate has an off angle of not less than 50° and not more than 65° relative to the (000-1) plane of the silicon carbide substrate. More preferably, the off orientation of the front-side surface forms an angle of 5° or smaller with the <1-100> direction of the silicon carbide substrate. More preferably, the front-side surface of the silicon carbide substrate has an off angle of not less than −3° and not more than 5° relative to the (0-33-8) plane in the <1-100> direction of the silicon carbide substrate. Utilization of such a crystal structure achieves high channel mobility in a semiconductor device that employs combined substrate 81. It should be noted that the “off angle of the front-side surface relative to the (0-33-8) plane in the <1-100> direction” refers to an angle formed by an orthogonal projection of a normal line of the front-side surface to a projection plane defined by the <1-100> direction and the <0001> direction, and a normal line of the (0-33-8) plane. The sign of positive value corresponds to a case where the orthogonal projection approaches in parallel with the <1-100> direction whereas the sign of negative value corresponds to a case where the orthogonal projection approaches in parallel with the <0001> direction. Further, as a preferable off orientation of the front-side surface, the following off orientation can be employed apart from those described above: an off orientation forming an angle of 5° or smaller relative to the <11-20> direction of silicon carbide substrate 11.

Specifically, for example, each one in silicon carbide substrate group 10 is prepared by cutting, along the (0-33-8) plane, a SiC ingot grown in the (0001) plane in the hexagonal system. The (0-33-8) plane side is employed for the front-side surface thereof, and the (03-38) plane side is employed for the backside surface thereof. This allows for particularly higher channel mobility in each of the front-side surfaces. Preferably, the normal line direction of each of the side surfaces (FIG. 3: side surfaces S1 and S2, and the like) in silicon carbide substrate group 10 corresponds to one of <8-803> and <11-20>. This leads to increased growth rate in the in-plane direction of closing portion 21 (lateral direction in FIG. 13), whereby closing portion 21 closes more quickly.

For fast closing of closing portion 21, the front-side surface of each one in silicon carbide substrate group 10 has a normal line direction corresponding to <0001>. Preferably, the normal line direction of each of the side surfaces (FIG. 3: side surfaces S1 and S2, and the like) in silicon carbide substrate group 10 corresponds to one of <1-100> and <11-20>. This leads to increased growth rate in the in-plane direction of closing portion 21 (lateral direction in FIG. 13), whereby closing portion 21 closes more quickly.

### Second Embodiment

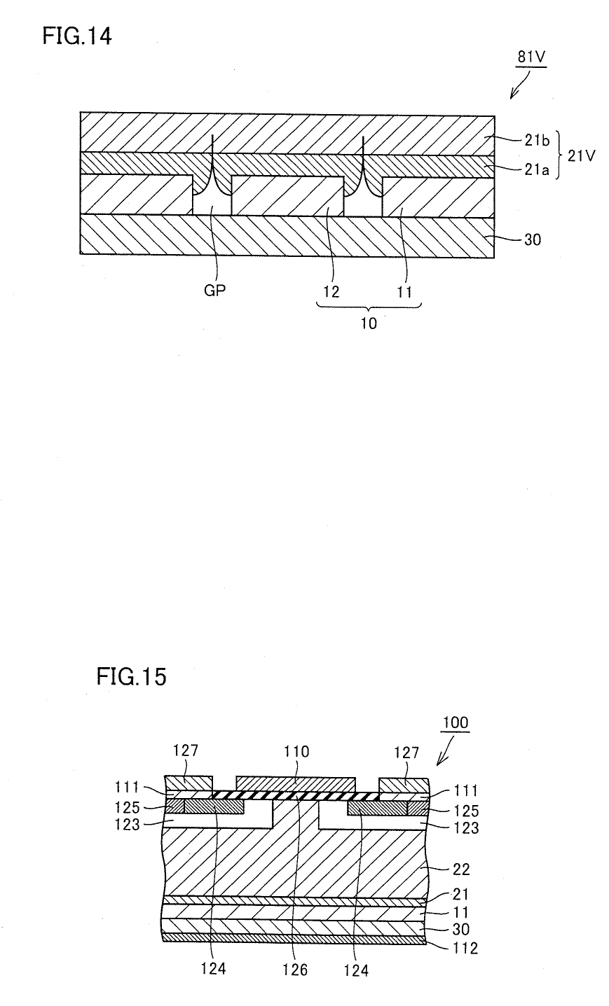

As shown in FIG. 14, a closing portion 21V of a combined substrate 81V of the present embodiment includes a first portion 21a located on silicon carbide substrates 11 and 12, and a second portion 21b located on first portion 21a. Second portion 21b has an impurity concentration lower than that of first portion 21a. Accordingly, second portion 21b can be used as a breakdown voltage holding layer having a particularly low impurity concentration in a semiconductor device.

Apart from the configuration described above, the configuration of the present embodiment is substantially the same as the configuration of the first embodiment. Hence, the same or corresponding elements are given the same reference characters and are not described repeatedly.

### Third Embodiment

In the present embodiment, the following describes manufacturing of a semiconductor device employing combined substrate 81 (FIG. 1 and FIG. 2). For ease of description, only silicon carbide substrate 11 of silicon carbide substrate group 10 provided in combined substrate 81 may be explained but the same explanation also applies to the other silicon carbide substrates thereof.

Referring to FIG. 15, a semiconductor device 100 of the present embodiment is a DiMOSFET (Double Implanted Metal Oxide Semiconductor Field Effect Transistor) of vertical type, and has supporting portion 30, silicon carbide substrate 11, closing portion 21 (buffer layer), a breakdown voltage holding layer 22, p regions 123, n⁺ regions 124, p⁺ regions 125, an oxide film 126, source electrodes 111, upper source electrodes 127, a gate electrode 110, and a drain electrode 112. Semiconductor device 100 has a planar shape (shape when viewed from upward in FIG. 15) of, for example, a rectangle or a square with sides each having a length of 2 mm or greater.

Drain electrode 112 is provided on supporting portion 30 and buffer layer 21 is provided on silicon carbide substrate 11. With this arrangement, a region in which flow of carriers is controlled by gate electrode 110 is disposed not on supporting portion 30 but on silicon carbide substrate 11.

Each of supporting portion 30, silicon carbide substrate 11, and buffer layer 21 has n type conductivity. Further, impurity with n type conductivity in buffer layer 21 has a concentration of, for example, 5×10¹⁷ cm⁻³. Further, buffer layer 21 has a thickness of, for example, 0.5 μm.

Breakdown voltage holding layer 22 is formed on buffer layer 21, and is made of SiC with n type conductivity. For example, breakdown voltage holding layer 22 has a thickness of 10 μm, and includes a conductive impurity of n type at a concentration of 5×10¹⁵ cm⁻³.

Breakdown voltage holding layer 22 has a surface in which the plurality of p regions 123 of p type conductivity are formed with a space therebetween. In each of p regions 123, an n⁺ region 124 is formed at the surface layer of p region 123. Further, at a location adjacent to n⁺ region 124, a p⁺ region 125 is formed. Oxide film 126 is formed on an exposed portion of breakdown voltage holding layer 22 between the plurality of p regions 123. Specifically, oxide film 126 is formed to extend on n⁺ region 124 in one p region 123, p region 123, the exposed portion of breakdown voltage holding layer 22 between the two p regions 123, the other p region 123, and n⁺ region 124 in the other p region 123. On oxide film 126, gate electrode 110 is formed. Further, source electrodes 111 are formed on n⁺ regions 124 and p⁺ regions 125. On source electrodes 111, upper source electrodes 127 are formed.

The maximum value of nitrogen atom concentration is equal to or greater than 1×10²¹ cm⁻³ in a region within not more than 10 nm from an interface between oxide film 126 and each of n⁺ regions 124, p⁺ regions 125, p regions 123, and breakdown voltage holding layer 22, each of which serves as a semiconductor layer. This achieves improved mobility particularly in a channel region below oxide film 126 (a contact portion of each p region 123 with oxide film 126 between each of n⁺ regions 124 and breakdown voltage holding layer 22).

The following describes a method for manufacturing a semiconductor device 100.

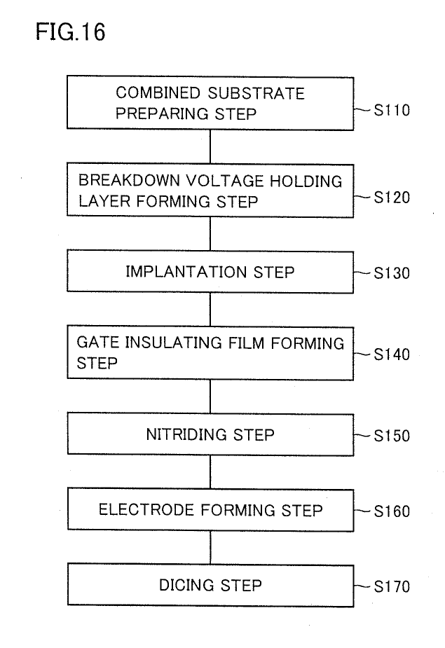

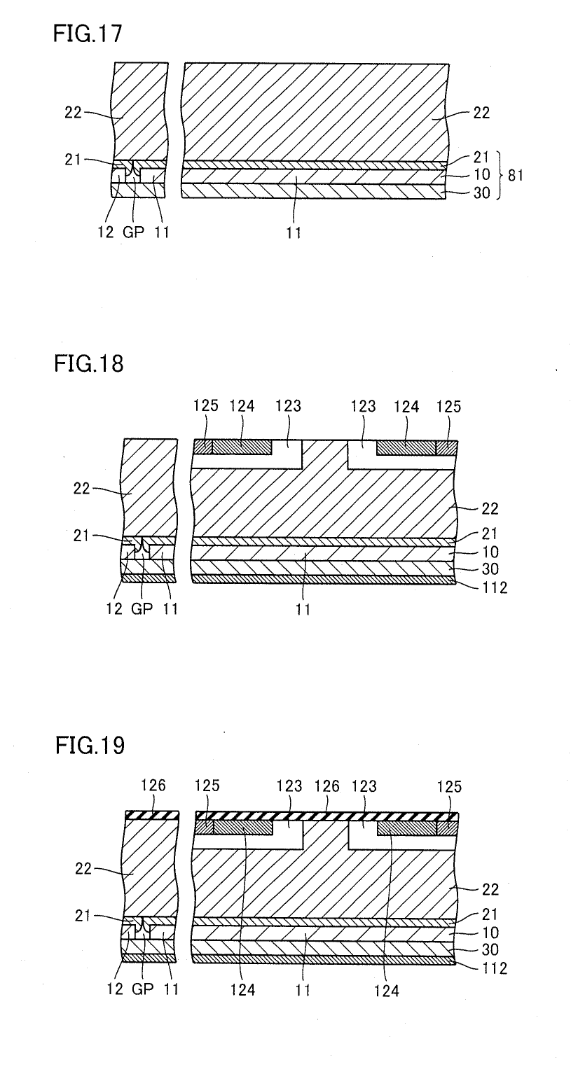

As shown in FIG. 17, first, combined substrate 81 (FIG. 1 and FIG. 2) is prepared (FIG. 16: step S110). Preferably, the front-side surface of closing portion 21 (buffer layer) is polished. Further, buffer layer 21 is made of silicon carbide of n type conductivity, and is an epitaxial layer having a thickness of 0.5 μm, for example. Buffer layer 21 has a conductive impurity at a concentration of, for example, 5×10¹⁷ cm⁻³.

Next, breakdown voltage holding layer 22 is formed on buffer layer 21 (FIG. 16: step S120). Specifically, a layer made of silicon carbide of n type conductivity is formed using an epitaxial growth method. Breakdown voltage holding layer 22 has a thickness of, for example, 10 μm. Further, breakdown voltage holding layer 22 includes an impurity of n type conductivity at a concentration of, for example, 5×10¹⁵ cm⁻³.

As shown in FIG. 18, an implantation step (step S130: FIG. 16) is performed to form p regions 123, n⁺ regions 124, and p⁺ regions 125 as follows.

First, an impurity of p type conductivity is selectively implanted into portions of breakdown voltage holding layer 22, thereby forming p regions 123. Then, a conductive impurity of n type is selectively implanted into predetermined regions to form n⁺ regions 124, and a conductive impurity of p type is selectively implanted into predetermined regions to form p⁺ regions 125. It should be noted that such selective implantation of the impurities is performed using a mask formed of, for example, an oxide film.

After such an implantation step, an activation annealing process is performed. For example, the annealing is performed in argon atmosphere at a heating temperature of 1700° C. for 30 minutes.

As shown in FIG. 19, a gate insulating film forming step (FIG. 16: step S140) is performed. Specifically, oxide film 126 is formed to cover breakdown voltage holding layer 22, p regions 123, n⁺ regions 124, and p⁺ regions 125. Oxide film 126 may be formed through dry oxidation (thermal oxidation). Conditions for the dry oxidation are, for example, as follows: the heating temperature is 1200° C. and the heating time is 30 minutes.

Thereafter, a nitriding step (FIG. 16: step S150) is performed. Specifically, annealing process is performed in nitrogen monoxide (NO) atmosphere. Conditions for this process are, for example, as follows: the heating temperature is 1100° C. and the heating time is 120 minutes. As a result, nitrogen atoms are introduced into a vicinity of the interface between oxide film 126 and each of breakdown voltage holding layer 22, p regions 123, n⁺ regions 124, and p⁺ regions 125.

It should be noted that after the annealing step using nitrogen monoxide, additional annealing process may be performed using argon (Ar) gas, which is an inert gas. Conditions for this process are, for example, as follows: the heating temperature is 1100° C. and the heating time is 60 minutes.

Next, an electrode forming step (FIG. 16: step S160) is performed to form source electrodes 111 and drain electrode 112 in the following manner.

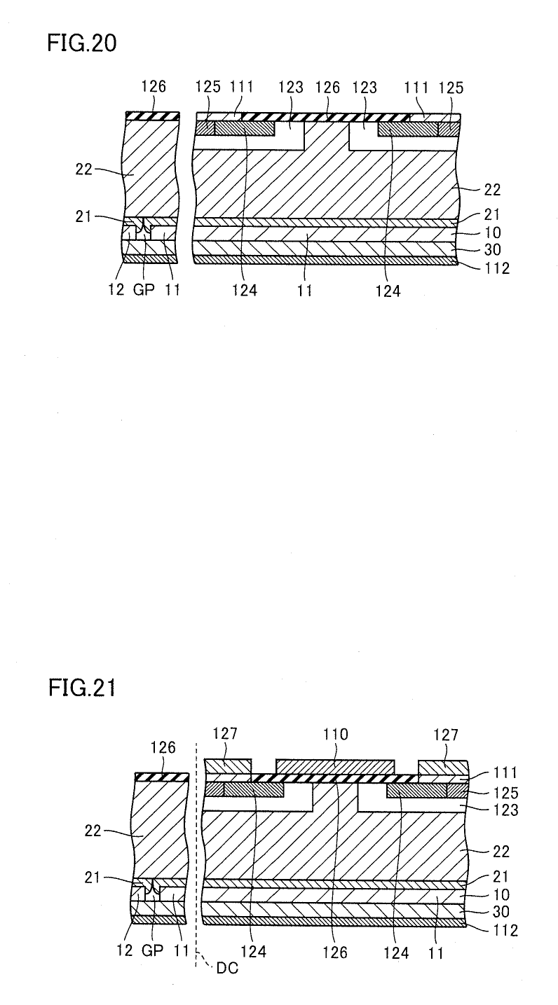

As shown in FIG. 20, a resist film having a pattern is formed on oxide film 126, using a photolithography method. Using the resist film as a mask, portions above n⁺ regions 124 and p⁺ regions 125 in oxide film 126 are removed by etching. In this way, openings are formed in oxide film 126. Next, in each of the openings, a conductive film is formed in contact with each of n⁺ regions 124 and p⁺ regions 125. Then, the resist film is removed, thus removing the conductive film's portions located on the resist film (lift-off). This conductive film may be a metal film, for example, may be made of nickel (Ni). As a result of the lift-off, source electrodes 111 are formed.

It should be noted that on this occasion, heat treatment for alloying is preferably performed. For example, the heat treatment is performed in atmosphere of argon (Ar) gas, which is an inert gas, at a heating temperature of 950° C. for two minutes.

Referring to FIG. 21, upper source electrodes 127 are formed on source electrodes 111. Further, gate electrode 110 is formed on oxide film 126. Further, drain electrode 112 is formed on the backside surface of combined substrate 81.

Next, in a dicing step (FIG. 16: step S170), dicing is performed as indicated by a broken line DC. Accordingly, a plurality of semiconductor devices 100 (FIG. 15) are obtained by the cutting.

It should be noted that as a variation of the present embodiment, combined substrate 81V (FIG. 14) can be used instead of combined substrate 81 (FIG. 1 and FIG. 2). In this case, buffer layer 21 of semiconductor device 100 can be formed by first portion 21a, and breakdown voltage holding layer 22 can be formed by second portion 21b.

Further, a configuration may be employed in which conductivity types are opposite to those in the present embodiment. Namely, a configuration may be employed in which p type and n type are replaced with each other. Further, the DiMOSFET of vertical type has been exemplified, but another semiconductor device may be manufactured using the combined substrate of the present invention. For example, a RESURF-JFET (Reduced Surface Field-Junction Field Effect Transistor) or a Schottky diode may be manufactured.

The embodiments disclosed herein are illustrative and non-restrictive in any respect. The scope of the present invention is defined by the terms of the claims, rather than the embodiments described above, and is intended to include any modifications within the scope and meaning equivalent to the terms of the claims.

### REFERENCE SIGNS LIST

10: silicon carbide substrate group; 11: silicon carbide substrate (first silicon carbide substrate); 12: silicon carbide substrate (second silicon carbide substrate); 21, 21V: closing portion (buffer layer); 21a: first portion; 21b: second portion; 22: breakdown voltage holding layer; 30: supporting portion; 40: filling portion; 41: polishing agent; 42: polishing cloth; 80: connected substrate; 81, 81V: combined substrate; 90: chamber; 100: semiconductor device.

1. A method for manufacturing a combined substrate, comprising the steps of:
preparing a connected substrate having a supporting portion and first and second silicon carbide substrates, said first silicon carbide substrate having a first backside surface connected to said supporting portion, a first front-side surface opposite to said first backside surface, and a first side surface connecting said first backside surface and said first front-side surface to each other, said second silicon carbide substrate having a second backside surface connected to said supporting portion, a second front-side surface opposite to said second backside surface, and a second side surface connecting said second backside surface and said second front-side surface to each other and forming a gap between said first side surface and said second side surface;
forming a filling portion for filling said gap;
polishing said first and second front-side surfaces after the step of forming said filling portion;
removing said filling portion after the step of polishing; and
forming a closing portion for closing said gap after the step of removing.

2. The method for manufacturing the combined substrate according to claim 1, wherein the step of forming said closing portion is performed by epitaxially growing said closing portion on said first and second silicon carbide substrates.

3. The method for manufacturing the combined substrate according to claim 1, wherein the step of removing said filling portion is performed by means of a dry process.

4. The method for manufacturing the combined substrate according to claim 1, wherein the step of forming said filling portion is performed using at least one of a metal, a resin, and silicon.

5. The method for manufacturing the combined substrate according to claim 1, wherein the step of removing said filling portion and the step of forming said closing portion are performed in a continuous manner in a chamber.
